(19) United States
(12) Patent Application Publication
(10) Pub. No.: US 2002/0189535 A1
(43) Pub. Date: Dec. 19, 2002

(54) Method for manufacturing semiconductor crystal film

(75) Inventors: Yoshihiko Kanzawa, Kadoma-shi (JP); Katsuya Nozawa, Osaka-shi (JP); Tohru Saitoh, Settsu-shi (JP); Minoru Kubo, Nabari-shi (JP)

Correspondence Address: NIXON PEABODY, LLP, 8180 GREENSBORO DRIVE, SUITE 800, MCLEAN, VA, 22102, US

(73) Assignee: MATSUSHITA ELECTRIC INDUSTRIAL CO., LTD., Osaka (JP)

(21) Appl. No.: 10/166,693

(22) Filed: Jun. 12, 2002

(30) Foreign Application Priority Data
Jun. 14, 2001 (JP) 2001-179586

(51) Int. Cl. C30B 23/00; C30B 25/00; C30B 28/12; C30B 28/14

(52) U.S. Cl. 117/105

(57) ABSTRACT

Source gases and atomic hydrogen are alternately supplied onto a substrate on which a crystal is to be grown. By exposing a surface of the substrate to the atomic hydrogen, the ratio of Ge atoms attached to H atoms to all Ge atoms present on the outermost surface where growth is proceeding is increased compared with that prior to the exposure to the atomic hydrogen. If H atoms are attached to Ge atoms on the outermost surface, the phenomenon occurs in which the Ge atoms are interchanged with Si atoms present in the underlying layer. As a result, a higher proportion of Ge atoms are interchanged with Si atoms than in a conventional manufacturing method which does not involve the exposure to the atomic hydrogen. This reduces the ratio of Ge atoms to all atoms on the outermost surface where growth is proceeding and renders C atoms having low affinity with Ge atoms more likely to occupy lattice positions in the crystal.

### BACKGROUND OF THE INVENTION

The present invention relates to a method for manufacturing a semiconductor crystal film having a crystal film containing Si, Ge, and C.

Semiconductor devices using an Si crystal have improved progressively in multifunctionality and high-speed property. This is mainly attributable to the miniaturization of their elements. To improve device performance in future, it is necessary to pursue further miniaturization. However, there are numerous technological problems to overcome in achieving any further device miniaturization. Even if miniaturization is promoted to an extremity, the maximum device performance is limited by the physical properties (e.g., mobility) of an Si crystal material. So long as the Si crystal material is used, it is difficult to drastically improve the device performance.

Under these circumstances, devices using a Group IV element mixed-crystal semiconductor, not the miniaturizing approach, have become a recent focus of attention. In particular, vigorous studies have been performed recently on silicon germanium carbon (Si_{1-x-y}GeₓC_{y}: 0≦x≦1, 0≦y≦1) which is a Group IV element mixed-crystal semiconductor containing C. An Si_{1-x-y}GeₓC_{y} crystal may be regarded as a material obtained by improving silicon germanium (Si₁₋ₓGeₓ: 0≦x≦1) that has been applied actually to devices. The Si_{1-x-y}GeₓC_{y} crystal has the following characteristics superior to those of the Si₁₋ₓGeₓ crystal.

The first characteristic of the Si_{1-x-y}GeₓC_{y} crystal is a compressive strain which is smaller than that of the Si₁₋ₓGeₓ crystal when it forms a heterojunction with the Si crystal for the reason described below.

If a heterojunction is formed between the Si₁₋ₓGeₓ crystal and the Si crystal, a large compressive strain is likely to occur since the Si₁₋ₓGeₓ crystal has a larger lattice constant than the Si crystal. If the compressive strain has occurred in the crystal, dislocation is likely to occur. This reduces the critical thickness of a film and limits the thickness of the film that can be deposited without involving the occurrence of dislocation. As a result, relaxation involving the occurrence of dislocation is more likely to occur during the heat treatment of the crystal. If C smaller in atomic radius than Si and Ge is added to the Si₁₋ₓGeₓ crystal, however, the resulting Si_{1-x-y}GeₓC_{y} crystal is smaller in lattice constant than the Si₁₋ₓGeₓ crystal. It has therefore been considered that a large compressive strain is less likely to occur in a crystal composed of the Si crystal and the Si_{1-x-y}GeₓC_{y} crystal grown epitaxially thereon and the thermal resistance thereof is also higher. In the Si_{1-x-y}GeₓC_{y} crystal having a C composition ratio y which is about 1/8 of a Ge composition ratio, the Si_{1-x-y}GeₓC_{y} crystal can be lattice-matched with the Si crystal.

The second characteristic of the Si_{1-x-y}GeₓC_{y} crystal is that a band offset occurs in each of the conduction and valence bands thereof when it forms a heterojunction with the Si crystal, as will be described below.

If the Si₁₋ₓGeₓ crystal and the Si crystal form a heterojunction therebetween, a band offset occurs only in the valence band region of the Si₁₋ₓGeₓ crystal and does not occur in the conduction band region in the band structure of a crystal. If a high-speed MOS transistor is formed by using the Si₁₋ₓGeₓ crystal portion as a channel, a p-channel transistor can therefore be produced but an n-channel transistor cannot be produced. If the Si_{1-x-y}GeₓC_{y} crystal and the Si crystal form a heterojunction therebetween, by contrast, it has been reported that a band offset occurs in each of the valence and conduction bands when the Ge and C contents of the Si_{1-x-y}GeₓC_{y} crystal are high (when the Ge content is several tens of atomic percent and the C content is several atomic percent) (K. Brunner et al., J.Vac.Sci.Technol. B16, 1701 (1998)). In this case, carriers can be confined to either of the conduction and valence bands. This allows the production of not only the p-channel transistor but also the n-channel transistor.

The third characteristic of the Si_{1-x-y}GeₓC_{y} crystal is that C has the property of suppressing the diffusion of an impurity such as B (boron). The property is extremely effective in producing a device in which the B profile should be controlled properly and is also effective in stabilizing a fabrication process for a semiconductor device. In fabricating, e.g., an ultra-high-speed npn bipolar transistor with a narrow base region or a field-effect transistor using γ-doping, the use of a semiconductor layer containing C for a region to be doped with B prevents the diffusion of B by a heat treatment and allows the production of a device having a doping profile exactly as designed.

Thus, the Si_{1-x-y}GeₓC_{y} crystal which is a Group IV crystal containing C is a material having properties superior to those of the Si crystal and the Si₁₋ₓGeₓ crystal.

However, the production of a high-quality Si_{1-x-y}GeₓC_{y} crystal is more difficult than the production of the Si₁₋ₓGeₓ crystal due to the intrinsic properties of C for the following reasons.

For one thing, the solid solubilities of C atoms with respect to the Si crystal and the Ge crystal are extremely low (about 10¹⁷/cm³ with respect to Si crystal and 10⁸/cm³ with respect to the Ge crystal in a thermally equilibrium state) so that it is difficult to produce a crystal containing C atoms at a high content (on the order of atomic percent) under a thermally equilibrium condition during a fluxing process or the like.

For another, C atoms have a disposition not only to occupy lattice positions in a crystal but also to enter interlattice spaces. For the sake of convenience, the present specification defines C atoms occupying lattice positions in a crystal as lattice-position C atoms and defines C atoms situated in interlattice spaces in a crystal as interlattice C atoms. In addition, C atoms have a tendency to be bonded selectively to Si atoms in crystal lattices. As a result, a structure close to an SiC crystal (a crystalline silicon carbide) or amorphous SiC is likely to be formed and such a localized structure causes the degradation of the crystal.

To produce the Si_{1-x-y}GeₓC_{y} crystal which is difficult to produce as described above, there have conventionally been used methods termed CVD (Chemical Vapor Deposition), gas source MBE (Molecular Beam Epitaxy), and solid source MBE. These methods and associated problems will be described herein below.

First, CVD and gas source MBE will be described. CVD and gas source MBE are alike in that they are crystal growing methods each involving the decomposition of a source gas over a substrate surface and crystal growth. In growing the Si_{1-x-y}GeₓC_{y} crystal on the Si crystal, it is normal to simultaneously supply a silane-based gas such as SiH₄ or Si₂H₆ as the source of Si composing the Si_{1-x-y}GeₓC_{y} crystal, a GeH₄ gas as the source of Ge, and a gas containing C such as SiH₃CH₃ or C₂H₂ as the source of C to a vacuum chamber, while the Si substrate is heated in the vacuum chamber. However, even if CVD or gas source MBE is performed, C is not allowed to freely occupy lattice positions in a crystal and the content of C occupying lattice positions has a limit value. If C is to be mixed in the crystal to achieve a content exceeding the limit value, the quality of the Si_{1-x-y}GeₓC_{y} crystal is extremely lowered. In particular, the Si_{1-x-y}GeₓC_{y} crystal having a small number of defects and an excellent crystalline property to a degree which allows the application thereof to a semiconductor device cannot be grown under the present circumstances unless the C content thereof is about 2 at. % or less.

A description will be given next to solid source MBE. If the Si_{1-x-y}GeₓC_{y} crystal is produced by solid source MBE, crystal growth is performed by applying, to the substrate, molecular beams generated by evaporating solid Si, Ge, and C in ultra-high vacuum. In general, Si and Ge molecular beams are generated in accordance with a method of applying electron beams to Si and Ge crystals and heating the Si and Ge crystals in a crucible. On the other hand, a C molecular beam is typically generated by heating and evaporating a graphite. It has recently been reported that, even if solid source MBE is performed, C is less likely to occupy lattice positions when the Ge content is high, similarly to the case where CVD is performed (J. P. Liu and H. J. Osten, Appl.Phys.Lett. 76, 3546 (2000)).

Thus, even in the case of adopting any of CVD and gas source MBE using source gases and solid source MBE using solid sources, each of which is used frequently to fabricate the Si_{1-x-y}GeₓC_{y} crystal, the content of C allowed to occupy lattice positions is lowered if the Ge content is increased.

The present inventors have proved that one of factors which make it difficult to simultaneously achieve Ge and C contents in the Si_{1-x-y}GeₓC_{y} crystal that are sufficient to allow the Si_{1-x-y}GeₓC_{y} crystal to be used for a semiconductor crystal film is low affinity between Ge atoms and C atoms and that the maximum content of C which occupies lattice positions in the Si_{1-x-y}GeₓC_{y} crystal varies depending on the content of Ge (Y. Kanzawa, K. Nozawa, T. Saitoh, and M. Kubo, Appl.Phys.Lett.77, 3962(2000)). FIG. 1 is a graph in which the maximum content of C allowed to occupy lattice positions is plotted as an ordinate axis and the content of Ge is plotted as an abscissa axis when the Si_{1-x-y}GeₓC_{y} crystal in a single layer is deposited by UHV-CVD on an Si substrate. As sources, an Si₂H₆ gas, a GeH₄ gas, and an SiH₃CH₃ gas were used. The temperature of the substrate during growth was adjusted to 490° C. As can be seen from FIG. 1, in the Si_{1-x-y}GeₓC_{y} crystal with a Ge content of about 13 at. %, the maximum content of C allowed to occupy lattice positions is about 1.9 at. %. In the Si_{1-x-y}GeₓC_{y} crystal with a Ge content of about 35 at. %, however, the maximum content of C allowed to occupy lattice positions is only about 0.8 at. %. This indicates that, as the Ge content is higher in the Si_{1-x-y}GeₓC_{y} crystal, the maximum content of C allowed to occupy lattice positions is lower.

### SUMMARY OF THE INVENTION

It is therefore an object of the present invention to increase the maximum solid solubility of C which is low due to the low affinity between Ge and C and thereby provide a method for manufacturing a semiconductor crystal film which can be used to fabricate various semiconductors.

A method for manufacturing a semiconductor crystal film according to the present invention is a method for epitaxially growing a crystal film containing Si, Ge, and C, the method comprising the steps of: epitaxially growing, on a substrate, a crystal layer containing Si, Ge, and C in at least one atomic layer; and covering at least a part of an upper surface of the crystal layer containing Si, Ge, and C with atomic hydrogen.

Compared with the conventional manufacturing method, the method according to the present invention increases the ratio of Ge atoms attached to H atoms to all Ge atoms present on the outermost surface of the substrate where the crystal is growing. If H atoms are attached to Ge atoms present on the outermost surface of the crystal, the phenomenon occurs in which the Ge atoms are interchanged with Si present in the underlying layer. In the manufacturing method according to the present invention, therefore, a larger number of Ge atoms are interchanged with Si atoms in the underlying layer than in the conventional manufacturing method. Accordingly, the ratio of Ge atoms to all atoms present on the outermost surface of the substrate where the crystal is growing is lowered so that the content of C in the crystal film containing Si, Ge, and C is increased.

In the method for manufacturing a semiconductor crystal film, the crystal layer containing Si, Ge, and C can be formed by thermally decomposing a source gas containing silicon (Si), a source gas containing germanium (Ge), and a source gas containing carbon (C). In this case, any of monosilane (SiH₄), disilane (Si₂H₆), dichlorosilane (SiH₂Cl₂), and trisilane (Si₃H₈) is used preferably as the source gas containing silicon (Si), germane (GeH₄) is used preferably as the source gas containing germanium (Ge), and monomethylsilane (SiH₃CH₃) is used preferably as the source gas containing carbon (C).

In the method for manufacturing a semiconductor crystal film, the crystal layer containing Si, Ge, and C can also be formed by applying, onto the substrate, an Si molecular beam, a Ge molecular beam, and a C molecular beam generated through evaporation of solid Si, solid Ge, and solid C.

The method for manufacturing a semiconductor crystal film can further comprise, after the step of epitaxially growing, on the substrate, the crystal layer containing Si, Ge, and C in at least one atomic layer: the step of covering at least a part of the upper surface of the crystal layer containing Si, Ge, and, C with the atomic hydrogen; and epitaxially growing the crystal layer containing Si, Ge, and C in at least one atomic layer.

In the method for manufacturing a semiconductor crystal film, the step of epitaxially growing the crystal layer containing Si, Ge, and C in at least one atomic layer and the step of supplying the atomic hydrogen can alternately be performed repeatedly.

In the method for manufacturing a semiconductor crystal film, supply of the atomic hydrogen and the epitaxial growth of the crystal layer containing Si, Ge, and C in at least one atomic layer can simultaneously be performed repeatedly.

The atomic hydrogen can be generated by using a plasma or a filament.

### BRIEF DESCRIPTION OF THE DRAWINGS

FIG. 1 is a graph in which the maximum content of C that can occupy lattice positions in an Si_{1-x-y}GeₓC_{y} layer formed by a conventional manufacturing method is plotted as an ordinate axis and a Ge content is plotted as an abscissa axis;

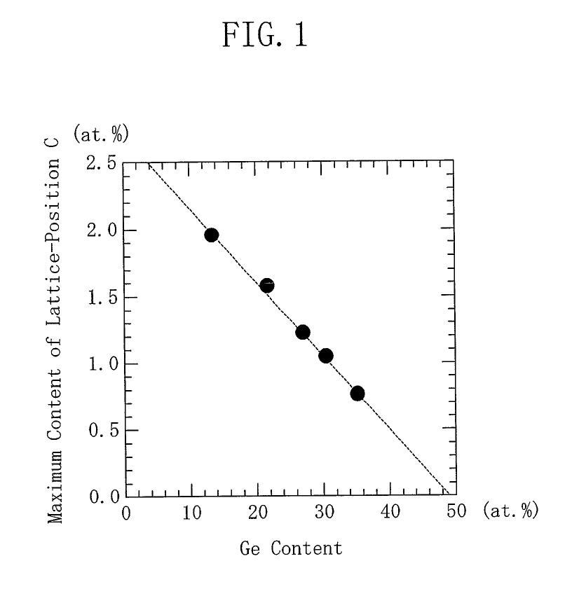

FIGS. 2A to 2D are cross-sectional views illustrating the steps of manufacturing a semiconductor crystal film according to a first embodiment of the present invention;

FIGS. 3A to 3C are cross-sectional views illustrating, of the steps of manufacturing the semiconductor crystal film according to the first embodiment, the steps prior and subsequent to the exposure of a substrate surface to atomic hydrogen;

FIGS. 4A to 4C are cross-sectional views illustrating the steps of manufacturing a semiconductor crystal film according to a second embodiment of the present invention; and

FIGS. 5A to 5D are cross-sectional views illustrating the steps of manufacturing a semiconductor crystal film according to a third embodiment of the present invention;

### DETAILED DESCIPTION OF THE INVENTION

Analysis of Si_{1-x-y}GeₓC_{y} Crystal Growing Process

The present inventors have considered that the following is one of the factors which render C atoms less likely to occupy lattice positions in a crystal as the Ge content x is higher. As the Ge content x in the Si_{1-x-y}GeₓC_{y} layer is higher, the ratio of Ge atoms to all atoms on the outermost surface thereof where crystal growth is proceeding is higher so that the ratio of Si atoms thereto is lower. Since the affinity between C atoms and Ge atoms is lower than the affinity between C atoms and Si atoms, the region of the outermost surface of the growing crystal in which C atoms cannot be bonded increases. As a result, C atoms that can occupy lattice positions in the crystal during the epitaxial growth of the Si_{1-x-y}GeₓC_{y} layer are assumedly reduced in number.

If the ratio of Ge atoms to all atoms present on the outer surface of the growing crystal is lower and the ratio of Si atoms thereto is higher, C atoms can occupy lattice positions in the crystal to achieve a rather high content in newly forming an Si_{1-x-y}GeₓC_{y} layer on the outermost surface of the growing crystal. In growing the crystal, if a reduction is achieved in the ratio of Ge atoms to all atoms present on the outermost surface on which the Si_{1-x-y}GeₓC_{y} layer with a high Ge content is to be deposited, it follows that C atoms are more likely to enter the Si_{1-x-y}GeₓC_{y} layer newly deposited.

As a method for reducing the ratio of Ge atoms to all atoms present on the outermost surface of the substrate in forming an Si_{1-x-y}GeₓC_{y} crystal, the present invention therefore proposes a method of growing the Si_{1-x-y}GeₓC_{y} crystal by supplying sourcegases and atomic hydrogen onto the substrate.

Embodiment 1

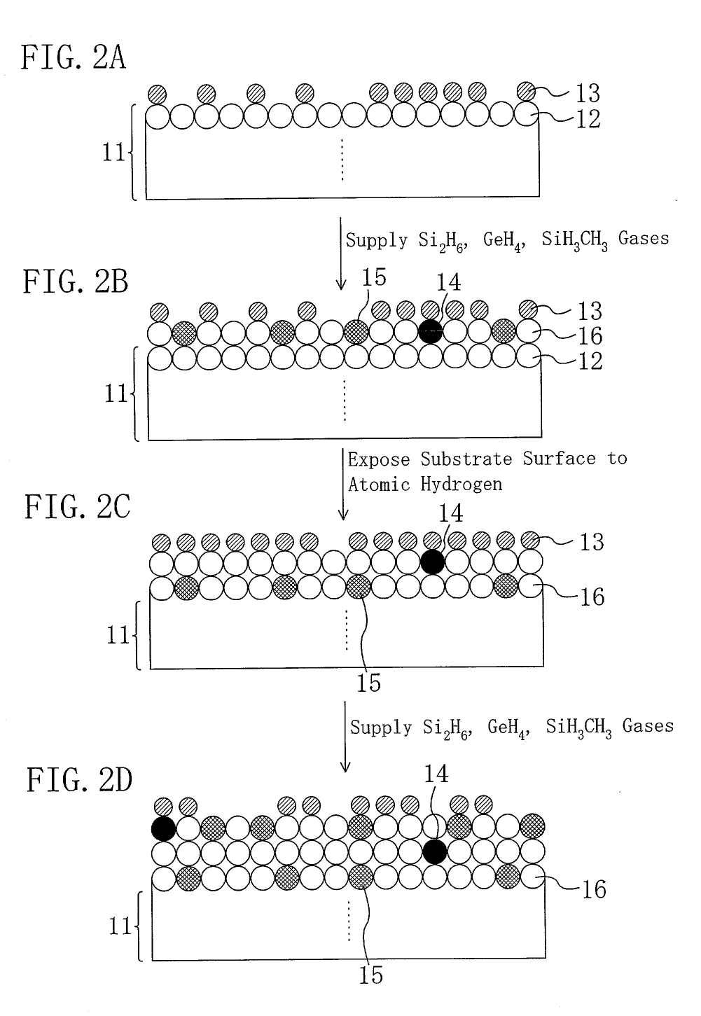

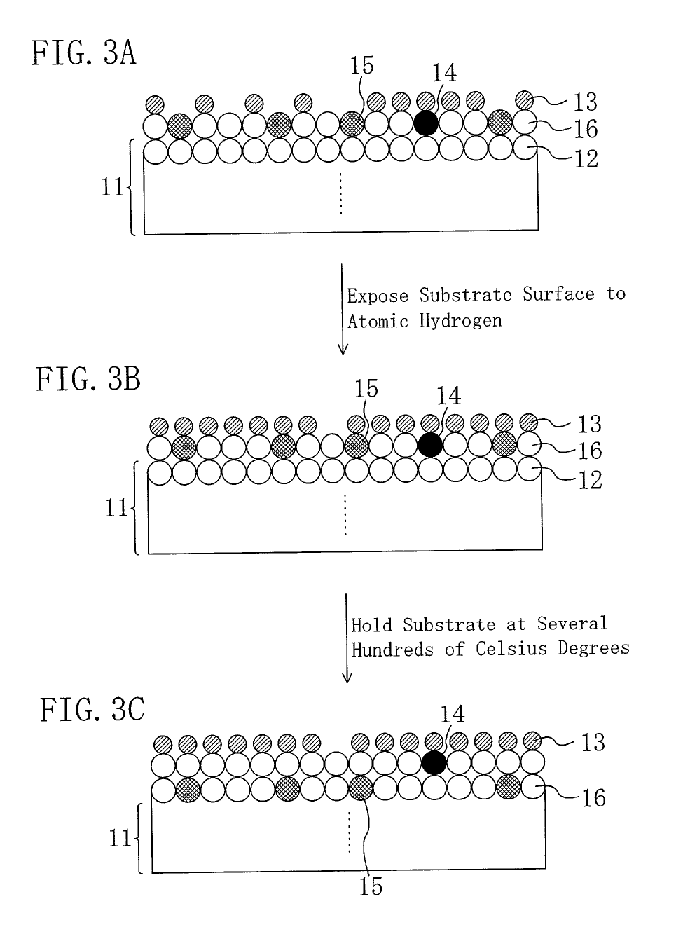

A method for manufacturing a semiconductor crystal film according to a first embodiment of the present invention will be described with reference to FIGS. 2A to 2D and FIGS. 3A to 3C. First, the steps of epitaxially growing an Si_{1-x-y}GeₓC_{y} layer will be described with reference to FIGS. 2A to 2D.

First, in the step shown in FIG. 2A, an Si substrate 11 on which a crystal is to be grown is cleaned. Specifically, the Si substrate 11 is cleaned in an aqueous solution mixture of sulfuric acid and hydrogen peroxide so that an organic substance and a metal contaminant on the surface of the Si substrate 11 are removed therefrom. Then, the Si substrate 11 is cleaned in an aqueous solution mixture of ammonia and hydrogen peroxide so that small particles on the surface of the Si substrate 11 are removed. Further, a natural oxide film on the surface of the Si substrate 11 is removed by using a hydrofluoric acid. Finally, the Si substrate 11 is immersed again in the aqueous solution mixture of ammonia and hydrogen peroxide, whereby a thin protective oxide film is formed on the surface of the Si substrate.

Next, the cleaned Si substrate 11 is introduced into a crystal growing apparatus. The crystal growing apparatus is temporarily evacuated to a pressure of about 2.6×10⁻⁷ Pa. The Si substrate 11 is heated in vacuum or in a hydrogen gas atmosphere to a temperature of 850° C. such that the protective oxide film formed on the surface of the Si substrate 11 in the foregoing cleaning step is removed therefrom and the surface of the cleaned Si substrate 11 is exposed. Of Si atoms 12 arranged on the outermost surface of the Si substrate 11, those in a given proportion are attached to H atoms 13. The other Si atoms are not bonded to H atoms 13 and have dangling bonds exposed.

Next, in the step shown in FIG. 2B, an Si_{1-x-y}GeₓC_{y} crystal is grown on the Si substrate 11. Specifically, the source gases of the Si_{1-x-y}GeₓC_{y} crystal are supplied to the upper surface of the Si substrate 11, while the temperature of the surface of the Si substrate 11 is lowered to about 490° C., whereby the crystal in about one atomic layer is grown. On the outermost surface of the grown crystal, Ge atoms 15 are present in a proportion of 100 x % (e.g., about 30 at. %). Besides, Si atoms 16 and C atoms 14 are assumedly present in a proportion of about 100 (1-x-y) % and in a proportion of about 100 y %, respectively. On the other hand, H atoms 13 are attached to a given proportion of atoms present on the outermost surface of the substrate. The respective partial pressures of the source gases are adjusted to be about 9.1×10⁻³ Pa for the Si₂H₆ gas, about 4.3×10⁻² Pa for the GeH₄ gas, and about 1.7×10⁻³ Pa for the SiH₃CH₃ gas. The crystal may be grown while the ratio between the partial pressures of the Si, Ge, and C source gases are held constant or varied.

Next, in the step shown in FIG. 2C, atomic hydrogen is supplied onto the substrate after the source gases were supplied thereto. As a result, substantially the entire outermost surface of the substrate is covered with H atoms, while the Ge atoms on the outermost surface of the substrate are assumedly bonded to the H atoms.

At this stage, the phenomenon occurs in which, of the Ge atoms 15 present on the outermost surface of the substrate, those attached to the H atoms are interchanged with Si atoms present in the layer underlying the Ge atoms. At that time, the substrate temperature is held at 500° C. or less, preferably at 400° C. or less. As an example of means for providing the atomic hydrogen, there is one which changes hydrogen molecules into atoms by means of a radical cell using, e.g., a helicon-wave plasma system. In that case, the atomic hydrogen is supplied appropriately under a pressure of about 6.5×10⁻⁴ Pa.

Next, in the step shown in FIG. 2D, the Si₂H₆ gas, the GeH₄ gas, and the SiH₃CH₃ gas as the source gases of the Si_{1-x-y}GeₓC_{y} crystal are supplied again onto the substrate after the atomic hydrogen was supplied thereto and then the atomic hydrogen is further supplied. Consequently, Ge contained in the newly formed Si_{1-x-y}GeₓC_{y} layer on the outermost surface moves to the underlying layer in which the Ge composition has been lowered. Accordingly, the Ge composition ratio in the underlying layer is assumedly restored to a level in a typical Si_{1-x-y}GeₓC_{y} crystal. By repeating the supply of the source gases of the Si_{1-x-y}GeₓC_{y} crystal and the supply of the atomic hydrogen, a layer in which Ge is distributed nearly evenly is formed except in the outermost surface layer.

In contrast to the conventional manufacturing method which does not supply the atomic hydrogen and allows only about 1.2 at. % C atoms to occupy lattice positions in the Si_{1-x-y}GeₓC_{y} crystal containing 30 at. % Ge, such technology allows about 1.6 at. % C atoms to occupy lattice positions in the Si_{1-x-y}GeₓC_{y} crystal containing 30 at. % Ge.

Referring to FIGS. 3A to 3C, a detailed description will be given next to the reason for an increased content of C atoms occupying lattice positions in the Si_{1-x-y}GeₓC_{y} crystal. FIGS. 3A to 3C are cross-sectional views illustrating, of the steps of growing the Si_{1-x-y}GeₓC_{y} crystal according to the present embodiment, the growth of the Si_{1-x-y}GeₓC_{y} crystal prior to and after exposure to the atomic hydrogen. For the sake of simplicity, FIGS. 3A to 3C depict the state in which the Si_{1-x-y}GeₓC_{y} crystal in one atomic layer is deposited on the Si substrate 11.

As shown in FIG. 3A, H atoms are attached with a given probability to Si atoms 16 and Ge atoms 15 present on the outermost surface of the substrate to which the source gases were supplied and the atomic hydrogen was not supplied. As the substrate temperature is higher, the proportions of Si and Ge atoms 16 and 15 attached to H atoms 15 are lower. Since H atoms 13 are more likely to be attached to Si atoms 12 than to Ge atoms 15, the ratio of Ge atoms attached to H atoms 13 to all Ge atoms 15 present on the outermost surface of the substrate is assumedly lower.

If the surface of the substrate in the foregoing state is exposed to the atomic hydrogen in the step shown in FIG. 3B, substantially the entire outermost surface of the substrate is covered with the atomic hydrogen. As a result, each of the ratios of Si atoms 15 and Ge atoms 16 attached to H atoms 13 to all Si and Ge atoms present on the outermost surface of the substrate increases.

If a heat treatment is performed continuously at a temperature lower than about 500° C. with respect to the substrate surface exposed to the atomic hydrogen in FIG. 3C, the phenomenon occurs in which those of all Ge atoms 15 present on the outermost surface of the substrate which are attached to H atoms are interchanged with Si atoms present in the layer underlying the Ge atoms. This is because, under such conditions, the interchange of the Ge atoms with the Si atoms provides higher stability in terms of energy (Y. Kobayashi, K. Sumitomo, K. Shiraishi, T. Urisu and T. Ogino, Surf.Sci. 436, 9(1999)).

Although all Ge atoms satisfying the foregoing condition have been interchanged with Si atoms present in the underlying layer in FIG. 3C, all the Ge atoms are not necessarily interchanged with the Si atoms. If the substrate temperature is raised to a level excessively higher than 500° C. after the atomic hydrogen was supplied to the substrate, H atoms attached to the outermost surface of the substrate are more likely to leave. By adjusting the substrate temperature to a level lower than about 500° C., therefore, the outermost surface of the substrate can be covered more positively with H atoms and the interchange of Ge atoms with Si atoms present in the stage underlying the Ge atoms can be promoted.

By thus supplying the atomic hydrogen onto the substrate, H atoms 13 are newly attached to atoms present on the outermost surface of the substrate so that the ratio of atoms attached to H atoms 13 to all atoms present on the outermost surface of the substrate becomes higher than before the atomic hydrogen was supplied. Accordingly, the ratio of Ge atoms attached to H atoms 13 to all Ge atoms 15 present on the outermost surface of the substrate also becomes higher than before the atomic hydrogen was supplied. In the manufacturing method according to the present embodiment, therefore, the probability of Ge atoms interchanged with Si atoms present in the underlying layer is higher than in the conventional method which does not involve exposure to the atomic hydrogen. The manufacturing method according to the present embodiment also reduces the ratio of Ge atoms to all atoms present on the outermost surface of the substrate when the source gases of the crystal are supplied and renders C atoms supplied from the sourcegas more likely to occupy lattice positions in the crystal.

As stated previously in the description of the prior art, one of the major factors which render C atoms less likely to occupy lattice positions is the low affinity between C atoms and Ge atoms. Since the manufacturing method according to the present embodiment moves Ge atoms having low affinity with C atoms to an atomic layer underlying an atomic layer on the outermost surface of the substrate when the Si_{1-x-y}GeₓC_{y} layer is newly deposited thereon and thereby lowers the density of Ge atoms on the outermost surface, the ratio of lattice-position C atoms can be increased.

Embodiment 2

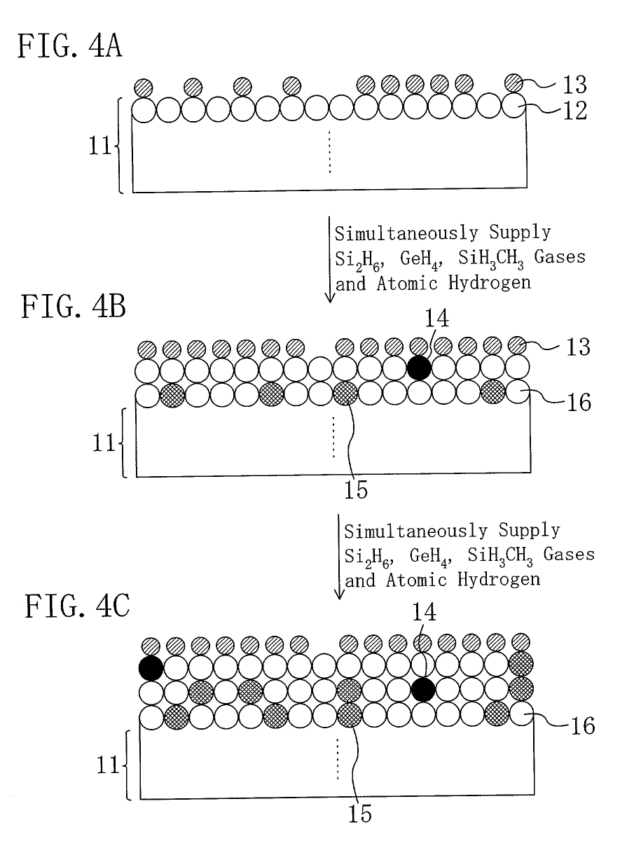

A method for manufacturing a semiconductor crystal film according to a second embodiment of the present invention will be described with reference to FIGS. 4A to 4C.

As a method for lowering the ratio of Ge atoms to all atoms present on the outermost surface of a substrate when an Si_{1-x-y}GeₓC_{y} crystal is grown thereon, the present embodiment adopts a method of providing an Si_{1-x-y}GeₓC_{y} layer by using UHV-CVD and simultaneously supplying source gases and atomic hydrogen onto the substrate.

First, in the step shown in FIG. 4A, a preparatory process including a cleaning process is performed with respect to an Si substrate in accordance with the same method as described in the first embodiment and then a surface of the clean Si substrate 11 is exposed by heating the Si substrate in ultra-high vacuum.

Next, in the step shown in FIG. 4B, the temperature of the Si substrate 11 is lowered to a level on the order of, e.g., 490° C. and then the source gases and the atomic hydrogen are supplied simultaneously onto the Si substrate 11. The source gases and the atomic hydrogen are supplied preferably at a temperature of about 500° C. or less. The setting of the temperature range simultaneously effects the growth of the Si_{1-x-y}GeₓC_{y} layer and the diffusion of Ge atoms into the underlying layer. The respective pressures of the source gases in an apparatus are adjusted to be about 9.1×10⁻³ Pa for the Si₂H₆ gas, about 4.3×10⁻² Pa for the GeH₄ gas, and about 1.7×10⁻³ Pa for the SiH₃CH₃ gas. The atomic hydrogen is obtained by changing H molecules into atoms by means of a radical cell using, e.g., a helicon-wave plasma system and supplied under a pressure of about 6.5×10⁻⁴ Pa.

If crystal growth is performed under such conditions, the atomic hydrogen can constantly be supplied to the outermost surface of the substrate where crystal growth is proceeding. Under substantially the same effects as achieved by the first embodiment, the ratio of atoms attached to H atoms to all atoms present on the outermost surface can therefore be held higher than in the conventional manufacturing method which does not supply the atomic hydrogen. Accordingly, the ratio of Ge atoms attached to H atoms to all Ge atoms present on the outermost surface also increases. As a result, a higher proportion of Ge atoms than in the conventional manufacturing method are interchanged with Si atoms present in the layer underlying the Ge atoms.

Then, in the step shown in FIG. 4C, the source gases and the atomic hydrogen are supplied simultaneously onto the substrate till a specified film thickness is obtained.

Compared with the case where the conventional manufacturing method is practiced, the foregoing steps according to the present embodiment lower the ratio of Ge atoms to all atoms on the outermost surface of the substrate where crystal growth is proceeding and conversely increases the ratio of Si atoms to all atoms on the outermost surface, so that C atoms are more likely to occupy lattice positions in the crystal. This increases the proportion of lattice-position C in the Si_{1-x-y}GeₓC_{y} layer.

Embodiment 3

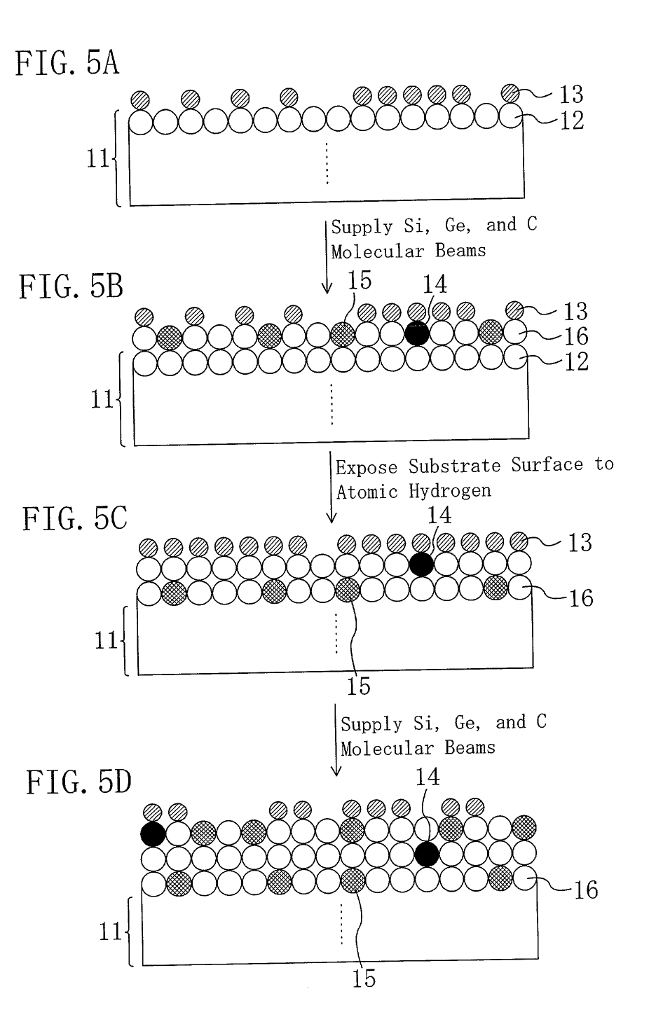

A method for manufacturing a semiconductor crystal film according to a third embodiment of the present invention will be described with reference to FIGS. 5A to 5D.

As a method for lowering the ratio of Ge atoms to all atoms present on the outermost surface of a substrate when an Si_{1-x-y}GeₓC_{y} layer is grown thereon, the present embodiment proposes a method of growing the Si_{1-x-y}GeₓC_{y} layer by using solid source MBE and alternately supplying Si, Ge, and C molecular beams and atomic hydrogen.

First, in the step shown in FIG. 5A, i.e., in the same step as described in the first embodiment, a preparatory process including a cleaning process is performed with respect to an Si substrate 11 and then a surface of the clean Si substrate 11 is exposed by heating the Si substrate 11 in ultra-high vacuum.

Next, in the step shown in FIG. 5B, the temperature of the Si substrate 11 is lowered to a level on the order of, e.g., 400° C. and then the Si, Ge, and C molecular beams are applied to the Si substrate 11 to grow the Si_{1-x-y}GeₓC_{y} crystal in about one atomic layer. The Si and Ge molecular beams are generated by, e.g., applying respective electron beams to an Si crystal and a Ge crystal and thereby evaporating Si and Ge. On the other hand, the C molecular beam is generated by heating a graphite filament through the passage of a current therethrough and partially evaporating the graphite. Such solid source MBE has an advantage of allowing the Si_{1-x-y}GeₓC_{y} layer to be grown even at a low temperature.

Next, in the step shown in FIG. 5C, the substrate surface is exposed to the atomic hydrogen after the supply of the Si, Ge, and C molecular beams was stopped. The atomic hydrogen is generated by means of a radical cell using, e.g., a helicon-wave plasma system. By thus exposing the substrate surface to the atomic hydrogen, the ratio of atoms attached to hydrogen to all atoms on the outermost surface where the crystal is growing is increased. As a result, a larger number of Ge atoms are interchanged with Si in the underlying layer than in the conventional manufacturing method.

Then, in the step shown in FIG. 5D, the supply of the Si, Ge, and C molecular beams and the supply of the atomic hydrogen onto the substrate are repeatedly performed till a specified film thickness is obtained.

Compared with the case where the conventional manufacturing method is practiced, the foregoing steps according to the present embodiment lower the ratio of Ge atoms to all atoms on the outermost surface of the substrate where crystal growth is proceeding and conversely increases the ratio of Si atoms to all atoms on the outermost surface, so that C atoms are more likely to occupy lattice positions in the crystal. This increases the proportion of lattice-position C in the Si_{1-x-y}GeₓC_{y} layer.

Embodiment 4

A method for manufacturing a semiconductor crystal film according to a fourth embodiment of the present invention will be described herein below.

As a method for lowering the ratio of Ge atoms to all atoms present on the outermost surface of a substrate when an Si_{1-x-y}GeₓC_{y} layer is grown thereon, the present embodiment uses a method of growing the Si_{1-x-y}GeₓC_{y} layer by using solid source MBE and simultaneously supplying Si, Ge, and C molecular beams and atomic hydrogen.

First, in the same step as described in the first embodiment, a preparatory process including a cleaning process is performed with respect to an Si substrate and then a surface of the clean Si substrate is exposed by heating the Si substrate in ultra-high vacuum.

Next, the temperature of the Si substrate is lowered to a level on the order of, e.g., 400° C. and then the Si, Ge, and C molecular beams and the atomic hydrogen are supplied simultaneously onto the substrate to grow the Si_{1-x-y}GeₓC_{y} crystal in about one atomic layer. The Si and Ge molecular beams are generated by applying respective electron beams to an Si crystal and a Ge crystal and thereby evaporating Si and Ge. On the other hand, the C molecular beam is generated by heating a graphite filament through the passage of a current therethrough and partially evaporating the graphite. The atomic hydrogen is generated by means of a radical cell using, e.g., a helicon-wave plasma system. By thus growing the Si_{1-x-y}GeₓC_{y} layer, the atomic hydrogen is constantly supplied to the outermost surface of the substrate where the crystal is growing so that the ratio of atoms attached to hydrogen to all atoms on the outermost surface where the crystal is growing is held high. As a result, a larger number of Ge atoms are interchanged with Si in the underlying layer than in the conventional manufacturing method.

Then, the simultaneous supply of the Si, Ge, and C molecular beams and the atomic hydrogen is performed till a specified film thickness is obtained.

Compared with the case where the conventional manufacturing method is practiced, the foregoing steps according to the present embodiment lower the ratio of Ge atoms to all atoms on the outermost surface of the substrate where crystal growth is proceeding and conversely increases the ratio of Si atoms to all atoms on the outermost surface, so that C atoms are more likely to occupy lattice positions in the crystal. This increases the proportion of lattice-position C in the Si_{1-x-y}GeₓC_{y} layer.

Other Embodiments

Although each of the first and second embodiments has used UHV-CVD as a method for growing the crystal, the present invention can also use another CVD process such as LP-DVD or, alternatively, gas source MBE in which the partial pressures of sourcegases are held low.

Although each of the first and second embodiments has used Si₂H₆ as the source gas as described above, the present invention can also use SiH₄, SiH₂Cl₂, or Si₃H₈ instead.

Although each of the third and fourth embodiments has used the method of applying the electron beams for the generation of the Si and Ge molecular beams, a method of heating a crucible with a heater may also be used instead.

As described above in the first to fourth embodiments that the Si_{1-x-y}GeₓC_{y} crystal is grown appropriately in at least one atomic layer till the atomic hydrogen is supplied, the Si_{1-x-y}GeₓC_{y} crystal may be grown in at least one atomic layer or in several layers according to the present invention. This makes it possible to alternately repeat the process of growing several atomic layers and the process of covering the atomic layers with the atomic hydrogen.

Although each of the first to fourth embodiment has described the case where the Si_{1-x-y}GeₓC_{y} layer is grown directly on the Si substrate, the present invention may also interpose a buffer layer composed of Si or Si₁₋ₓGeₓ between the Si substrate and the Si_{1-x-y}GeₓC_{y} layer.

Although each of the first to fourth embodiment has described the method of using the radical cell using the helicon-wave plasma system as a method for generating the atomic hydrogen, the present invention may also use thermal decomposition caused by heating a filament.

It has been described in each of the first to fourth embodiments that Ge attached to the atomic hydrogen are interchanged with Si located in the underlying layer by exposing the substrate surface to the atomic hydrogen and then holding the substrate temperature. In the present invention, however, the time at which the substrate surface is exposed to the atomic hydrogen need not be distinguished from the time at which the foregoing interchange occurs.

Although each of the first to fourth embodiment has described the case where the Si_{1-x-y}GeₓC_{y} layer is grown on the Si layer, the present invention may also grow the Si_{1-x-y}GeₓC_{y} layer on a layer other than the Si layer, such as the Si₁₋ₓGeₓ layer.

Although each of the first and third embodiments has described the case where hydrogen molecules are decomposed into the atomic hydrogen outside the crystal growing apparatus, the present invention may also decompose hydrogen molecules within the crystal growing apparatus to supply the atomic hydrogen. In the first embodiment, e.g., the atomic hydrogen may also be generated by stopping the supply of the sourcegases of the Si_{1-x-y}GeₓC_{y} crystal in the step shown in FIG. 2B and then decomposing hydrogen molecules within the apparatus by using a filament or the like.

The conditions under which the present invention is practiced are not limited to those (including gas species, pressure, and temperature) described in the first to fourth embodiments.

What is claimed is:

1. A method for manufacturing a semiconductor crystal film, the method comprising the steps of:
epitaxially growing, on a substrate, a crystal layer containing Si, Ge, and C in at least one atomic layer; and
covering at least a part of an upper surface of the crystal layer containing Si, Ge, and C with atomic hydrogen.

2. The method of claim 1, wherein the crystal layer containing Si, Ge, and C is formed by thermally decomposing a source gas containing silicon (Si), a source gas containing germanium (Ge), and a source gas containing carbon (C).

3. The method of claim 1, wherein the crystal layer containing Si, Ge, and C is formed by applying, onto the substrate, an Si molecular beam, a Ge molecular beam, and a C molecular beam generated through evaporation of solid Si, solid Ge, and solid C.

4. The method of claim 1, further comprising, after the step of epitaxially growing, on the substrate, the crystal layer containing Si, Ge, and C in at least one atomic layer:
the step of covering at least a part of the upper surface of the crystal layer containing Si, Ge, and, C with the atomic hydrogen; and
epitaxially growing the crystal layer containing Si, Ge, and C in at least one atomic layer.

5. The method of claim 4, wherein the step of epitaxially growing the crystal layer containing Si, Ge, and C in at least one atomic layer and the step of supplying the atomic hydrogen are alternately performed repeatedly.

6. The method of claim 1, wherein supply of the atomic hydrogen and the epitaxial growth of the crystal layer containing Si, Ge, and C in at least one atomic layer are simultaneously performed repeatedly.

7. The method of claim 2, wherein any of monosilane (SiH₄), disilane (Si₂H₆), dichlorosilane (SiH₂Cl₂), and trisilane (Si₃H₈) is used as the source gas containing silicon (Si), germane (GeH₄) is used as the source gas containing germanium (Ge), and monomethylsilane (SiH₃CH₃) is used as the source gas containing carbon (C).

8. The method of claim 1, wherein the atomic hydrogen is generated by using a plasma or a filament.
